(19) United States
(12) Patent Application Publication
(10) Pub. No.: US 2025/0233122 A1
(43) Pub. Date: Jul. 17, 2025

(54) SCALABLE FABRICATION OF AMORPHOUS SILICON ANODE ELECTRODES FOR BATTERY CELLS

(71) Applicant: GM GLOBAL TECHNOLOGY OPERATIONS LLC, Detroit, MI (US)

(72) Inventors: Zhe LI, Shanghai (CN); Xingcheng XIAO, Troy, MI (US); Haijing LIU, Shanghai (CN)

(21) Appl. No.: 18/639,208

(22) Filed: Apr. 18, 2024

(30) Foreign Application Priority Data
Jan. 16, 2024 (CN) 2024100656156

(51) Int. Cl. H01M 4/04; C23C 14/16; C23C 14/35; C23C 14/56; H01M 4/02; H01M 4/134; H01M 4/1395; H01M 4/38

(52) U.S. Cl. CPC H01M 4/0426; C23C 14/165; C23C 14/352; C23C 14/562; H01M 4/0404; H01M 4/134; H01M 4/1395; H01M 4/386; H01M 2004/021; H01M 2004/027

(57) ABSTRACT

A method for manufacturing an anode electrode for a battery cell includes supplying a roughened anode current collector from a roll-to-roll chamber to a magnetron sputtering chamber; routing the roughened anode current collector around a roller in the magnetron sputtering chamber; using T sputtering targets arranged circumferentially around a portion of the roller, sputtering an amorphous silicon layer onto the roughened anode current collector to form an anode electrode, where T is an integer greater than one; and receiving the anode electrode from the magnetron sputtering chamber at the roll-to-roll chamber.

### CROSS-REFERENCE TO RELATED APPLICATIONS

This application claims the benefit of Chinese Patent Application No. 202410065615.6, filed on Jan. 16, 2024. The entire disclosure of the application referenced above is incorporated herein by reference.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells, and more particularly to anode electrodes and methods for manufacturing anode electrodes for battery cells.

Electric vehicles (EVs) such as battery electric vehicles (BEVs), hybrid vehicles, and/or fuel cell vehicles include one or more electric machines and a battery system including one or more battery cells, modules, and/or packs. A power control system is used to control charging and/or discharging of the battery system during charging and/or driving.

Battery cells include cathode electrodes, anode electrodes, and separators. The cathode electrodes include a cathode active material layer arranged on a cathode current collector. The anode electrodes include an anode active material layer arranged on an anode current collector.

### SUMMARY

A method for manufacturing an anode electrode for a battery cell includes supplying a roughened anode current collector from a roll-to-roll chamber to a magnetron sputtering chamber; routing the roughened anode current collector around a roller in the magnetron sputtering chamber; using T sputtering targets arranged circumferentially around a portion of the roller, sputtering an amorphous silicon layer onto the roughened anode current collector to form an anode electrode, where T is an integer greater than one; and receiving the anode electrode from the magnetron sputtering chamber at the roll-to-roll chamber.

In other features, the roughened anode current collector is made of a material selected from a group consisting of copper, stainless steel (SS), nickel (Ni), titanium (Ti), and tin (Sb). The roughened anode current collector has a roughness (Rz) in a range from 0.1 μm to 12 μm. A thickness of the roughened anode current collector is in a range from 0.1 μm to 40 μm. A thickness of the amorphous silicon layer is in a range from 0.1 μm to 20 μm.

In other features, the amorphous silicon layer comprises a plurality of silicon columns. A diameter of the plurality of silicon columns is in a range from 0.1 μm to 15 μm. An average areal capacity of the anode electrode is in a range from 4 to 30 mAh/cm².

In other features, a DC bias voltage of the magnetron sputtering chamber is in a range from 100V to 1000V. A cathode power of the magnetron sputtering chamber is in a range from 0.5 KW to 30 kW.

A battery cell includes A anode electrodes, wherein each of the A anode electrodes includes a roughened anode current collector. An anode active material layer includes an amorphous silicon layer deposited using physical vapor deposition (PVD) onto the roughened anode current collector C cathode electrodes including a cathode current collector and a cathode active material layer are arranged on the cathode current collector. The battery cell includes S separators, where A, C and S are integers greater than one.

In other features, the roughened anode current collector is made of a material selected from a group consisting of copper, stainless steel (SS), nickel (Ni), titanium (Ti), and tin (Sb). The roughened anode current collector has a roughness (Rz) in a range from 0.1 μm to 12 μm. A thickness of the roughened anode current collector is in a range from 0.1 μm to 40 μm. A thickness of the amorphous silicon layer on the roughened anode current collector is in a range from 0.1 μm to 20 μm. The amorphous silicon layer comprises a plurality of silicon columns.

In other features, a diameter of the plurality of silicon columns is in a range from 0.1 μm to 15 μm. An average areal capacity is in a range from 4 to 30 mAh/cm².

A system for manufacturing an anode electrode for a battery cell includes a roll-to-roll chamber and a magnetron chamber including a roller and T sputtering targets arranged circumferentially around a portion of the roller where T is an integer greater than one. The roll-to-roll chamber supplies a roughened anode current collector to the magnetron sputtering chamber. The roughened anode current collector is routed around the roller in the magnetron sputtering chamber. The T sputtering targets sputter an amorphous silicon layer onto the roughened anode current collector to form an anode electrode. The anode electrode is routed from the magnetron sputtering chamber to the roll-to-roll chamber.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross sectional view of an example of a battery cell including A anode electrodes, C cathode electrodes, and S separators according to the present disclosure;

FIG. 2A is a side cross section view of an example of a roughened current collector and an amorphous silicon layer PVD-deposited onto the current collector according to the present disclosure;

FIG. 2B is a plan view of an example of a roughened current collector and an amorphous silicon layer PVD-deposited onto the current collector according to the present disclosure;

FIG. 3 is a functional block diagram of an example of a magnetron for depositing amorphous silicon onto a roughened current collector;

FIG. 4 is a functional block diagram of an example of a magnetron for depositing amorphous silicon using multiple targets onto a roughened current collector in a roll-to-roll process according to the present disclosure;

FIGS. 5A and 5B illustrate an example of the anode electrode during charging and discharging according to the present disclosure;

FIG. 6 is a side cross sectional view of an example of a battery cell including the anode electrode with liquid electrolyte according to the present disclosure;

FIG. 7 is a side cross sectional view of an example of a battery cell including the anode electrode with solid electrolyte according to the present disclosure;

FIG. 8 are examples of scanning electron microscope images of top and side views of the anode electrode according to the present disclosure;

FIGS. 9A and 9B are examples of graphs of X-ray diffraction (XRD) profiles and Raman Spectrum, respectively, of the anode electrodes according to the present disclosure; and

FIGS. 10A and 10B are examples of graphs illustrating capacity and capacity retention percentage, respectively, as a function of cycles for the anode electrodes according to the present disclosure.

In the drawings, reference numbers may be reused to identify similar and/or identical elements.

### DETAILED DESCRIPTION

While battery cells according to the present disclosure are shown in the context of electric vehicles, the battery cells can be used in stationary applications and/or other applications.

Silicon is a promising candidate as an anode active material due to multiple lithium ion (Li⁺) diffusion paths and high theoretical capacity. Developing high performance sheet-type silicon anodes is important for constructing practical lithium-ion batteries. Generally, the sheet-type silicon anode is fabricated using a wet-coating method. However, delivered rate capability and cycling of the anode electrode still need to be enhanced.

The present disclosure relates to a method for manufacturing an anode electrode including an amorphous silicon anode layer (e.g., including silicon columns) deposited onto a roughened copper current collector. The anode electrode can be produced using a scalable roll-to-roll manufacturing process.

Conventional wet coating processes mix an anode active material, a conductive additive, a binder, and a solvent into a mixture. The mixture is cast onto an anode current collector and then a drying stage is used to remove the solvent. The solvent has environmental issues and the drying stage increase the footprint of the process.

The manufacturing method according to the present disclosure for the anode electrode uses magnetron sputtering. This approach eliminates the use of the binder, the conductive additive, and the solvent, which simplifies the silicon anode fabrication process while increasing energy density. In addition, the amorphous silicon layer includes accidented surfaces. The accidented surfaces enable more contact interfaces with the electrolyte to increase Li-ion conduction paths and help release stress during silicon volume change during cycling.

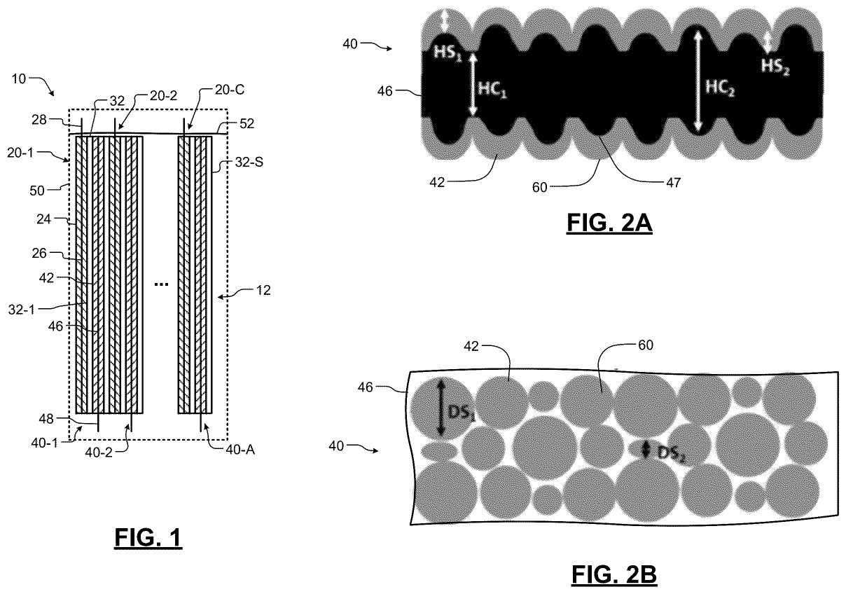

Referring now to FIG. 1, a battery cell 10 includes C cathode electrodes 20, A anode electrodes 40, and S separators 32 arranged in a predetermined sequence in a battery cell stack 12, where C, S and A are integers greater than zero. The battery cell stack 12 is arranged in an enclosure 50. The C cathode electrodes 20-1, 20-2, . . . , and 20-C include cathode active material layers 24 arranged on one or both sides of a cathode current collector 26. The A anode electrodes 40-1, 40-2, . . . , and 40-A include anode active material layers 42 arranged on an anode current collector 46. In some examples, the A anode electrodes 40 and the C cathode electrodes 20 exchange lithium ions during charging/discharging.

In some examples, the anode active material layer 42 includes a silicon layer PVD-deposited onto the anode current collector 46. The anode current collector 46 comprises a roughened current collector. In some examples, the cathode active material layers 24 comprise coatings including one or more active materials, one or more conductive additives, and/or one or more binder materials that are applied (cast or laminated) onto the current collectors.

In some examples, the cathode current collector 26 comprises metal foil, metal mesh, perforated metal, 3 dimensional (3D) metal foam, and/or expanded metal. In some examples, the cathode current collectors are made of one or more materials selected from a group consisting of stainless steel, brass, bronze, zinc, and aluminum. External tabs 28 and 48 are connected to the current collectors of the cathode electrodes and anode electrodes, respectively, and can be arranged on the same or different sides of the battery cell stack 12. The external tabs 28 and 48 are connected to terminals of the battery cells.

In some examples, the battery cell 10 uses liquid electrolyte 52. In other examples, a solid-solid electrolyte, a gel electrolyte, and/or liquid electrolyte are used.

Referring now to FIGS. 2A and 2B, one of the A anode electrodes 40 is shown in further detail. In FIG. 2A, the one of the A anode electrodes 40 includes the anode current collector 46 and the anode active material layer 42. In some examples, the anode current collector 46 includes roughened surfaces 47 on opposite sides thereof. The anode active material layer 42 includes an amorphous silicon layer 60 that is deposited using physical vapor deposition (PVD). The Si morphology will depend on the bias DC voltage and/or silicon cathode power during roll-to-roll fabrication process.

When the DC voltage is 100 to 500 V (e.g., 350-500V) and/or the cathode power is 0.5 to 12 KW (e.g., 10KW), the silicon is uniformly and gently deposited onto the roughened current collector to form silicon columns that include convex spherical surfaces. In some examples, a height of the amorphous silicon layer on roughened anode current collector (e.g., H_{S1}≈H_{S2}≈H_{Sn}) is in a range from 0.1 μm to 20 μm. In some examples, a diameter of the silicon columns (e.g., D_{S1}≈D_{S2}≈D_{Sn}) is in a range from 0.1 μm to 15 μm. In some examples, an average areal capacity is in a range from 4 to 30 mAh/cm² (e.g., 10 to 20 mAh/cm² for double-sided).

In some examples, the roughened anode current collector includes a roughened surface to enable tight interfaces with the amorphous silicon layer. In some examples, the roughened anode current collector has a roughness (Rz) in a range from 0.1 μm to 12 μm (e.g., 8 μm). In some examples, the thickness of the roughened anode current collector (e.g., H_{C1}, H_{C2}, H_{Cn}) is in a range from 0.1 μm to 40 μm. In some examples, the roughened anode current collector is made of a material selected from a group consisting of copper, stainless steel, nickel (Ni), titanium (Ti), and tin (Sn).

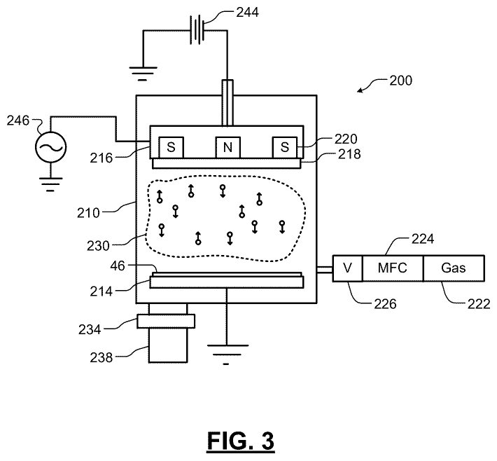

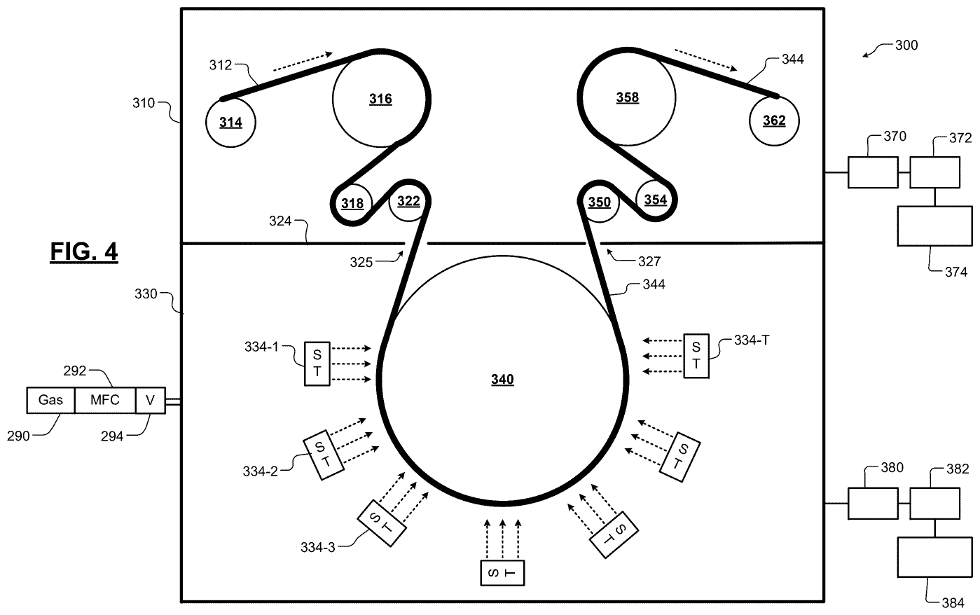

Referring now to FIGS. 3 and 4, description of a static DC magnetron sputtering device (FIG. 3) will be used to help illustrate a continuous DC magnetron sputtering device (FIG. 4) for continuously producing the anode electrode according to the present disclosure. In FIG. 3, a DC magnetron sputtering device 200 deposits the anode active material layer including amorphous silicon onto the roughened anode current collector 46. The roughened anode current collector 46 is arranged on a substrate support 214 in a processing chamber 210. A magnetron cathode 216 including magnets 220 and a target 218 are arranged spaced from the substrate support 214.

During deposition, a process gas mixture such as argon (Ar) from a gas source 222 is introduced into the processing chamber 210 while AC and/or DC power is supplied. In some examples, a mass flow controller 224 and a valve 226 are used to meter the process gas from the gas source 222 into the processing chamber 210. A throttle valve 234 and/or pump 238 control pressure within the processing chamber 210 and/or evacuate reactants from the processing chamber 210. A DC source 244 supplies DC voltage to the magnetron cathode 216. An AC source 246 supplies AC voltage to the magnetron cathode 216.

During deposition, a target material (e.g., silicon) is ejected from the target 218 and deposited on the roughened anode current collector 46. Material is also sputtered from an exposed surface of the roughened anode current collector 46. In some examples, a silicon target (e.g., n-type; 99.995%) sputters silicon particles onto a porous anode current collector (e.g., copper mesh). In some examples, the DC source 244 supplies DC voltage in a range from 100V to 1000V. In some examples, cathode power from the AC source 246 is in a range from 0.5 to 30 KW at a frequency in a range from 20 to 200 KHz. In some examples, the width of the current collector is in a range from 10 to 500 cm. In some examples, the process may be performed on the same side two or more times to increase the thickness of the amorphous silicon layer.

In some examples, the sputtering is performed on a continuous current collector in a roll-to-roll process. The speed of the roll to roll process is in the range from 2 m/min to 20 m/min. In some examples, the width of the anode current collector is in a range from 10 cm to 500 cm. Since this is a solvent-free fabrication process, there is no need for environmental control for solvent usage or drying stages to remove the solvent. The anode electrode has good mechanical flexibility which increases durability.

Referring now to FIG. 4, a continuous DC magnetron sputtering device 300 PVD deposits amorphous silicon onto a roughened current collector using multiple targets in a roll-to-roll process. A roll-to-roll chamber 310 houses a roll 314 supplying a roughened current collector 312. The roughened current collector 312 is fed around a roller 316, around tension rollers 318 and 322, and through an elongated hole 325 in a separating wall 324 (e.g., acting as a vacuum seal). The current collector 312 passes into a magnetron sputtering chamber 330 and onto a roller 340 acting as a rotating substrate support. The roller 340 is grounded. A plurality of sputtering targets 334-1, 334-2, . . . , and 334-T are arranged circumferentially around a portion of the roller 340, where T is an integer greater than one.

After the target sputters amorphous silicon onto the current collector 312 at the plurality of sputtering targets 334-1, 334-2, . . . , and 334-T, an electrode 344 (the current collector 312 and the sputtered amorphous silicon layer) exits the magnetron sputtering chamber 330 through an elongated hole 327 (e.g., acting as a vacuum seal) and enters the roll-to-roll chamber 310. The electrode 344 passes over tension rollers 350 and 354, around a roller 358, and is collected on a roll 362.

Vacuum within the roll-to-roll chamber 310 can be controlled using a valve 370 and a pump 372 connected to an exhaust system 374. Vacuum within the magnetron sputtering chamber 330 can be controlled using a valve 380 and a pump 382 connected to an exhaust system 384. A process gas mixture including one or more gases (e.g., argon (Ar)) can be supplied using one or more gas sources, mass flow controllers 292, and/or valves 294.

The roughened copper current collector (e.g., foil) is supplied using a roll-to-roll approach. A silicon layer is continuously deposited by a magnetron sputtering chamber in an argon atmosphere from multiple silicon targets onto the roughened copper current collector. After sputtering, the anode electrode is collected onto a roll. The process on the other side of the current collector to obtain double-side anode electrodes.

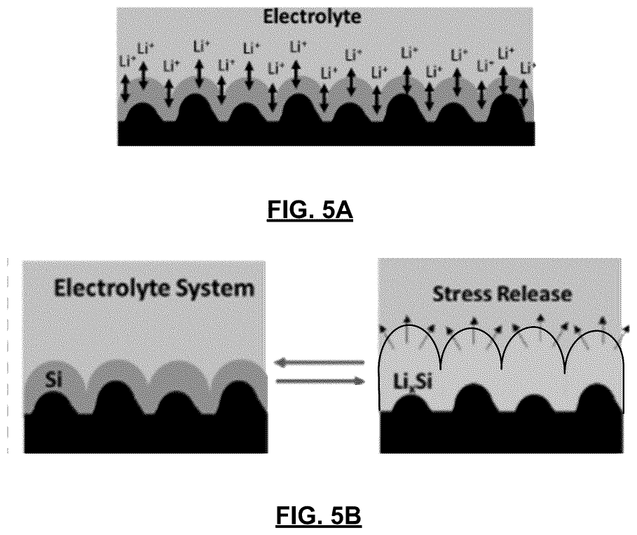

Referring now to FIGS. 5A and 5B, the anode electrode is illustrated during charging and discharging. The accidented spherical surfaces of Si enable more interfaces with electrolyte (e.g., solid electrolyte) to increase the Li-ion conduction paths, which enhances battery power capability. The accidented spherical surfaces help release the generated stress by Si expansion, which enhances battery cyclability.

The anode electrode described herein does not include the ionically insulating binder which enhances power capability. In addition, the carbon additive is removed which eliminates the adverse reactions with electrolyte (e.g., solid electrolyte) which prolongs the cell cycle life.

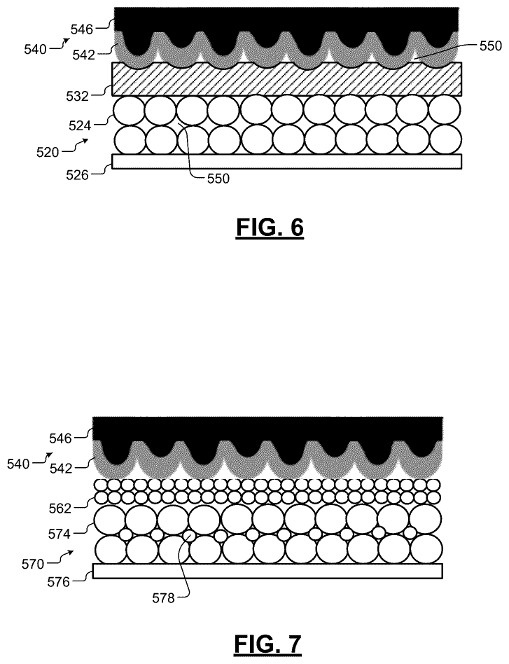

Referring now to FIGS. 6 and 7, the anode electrode can be used in battery cells with solid, liquid, and/or gel electrolyte. In FIG. 6, a battery cell includes an anode electrode 540 including an amorphous silicon active layer 542 arranged on a roughened current collector 546. A separator 532 includes a polymer separator. A cathode layer 520 includes a cathode active material layer 524 and a cathode current collector 526. Liquid electrolyte 550 (e.g., LiPF₆ in carbonate) is used.

In FIG. 7, a battery cell includes the anode electrode 540 including the amorphous silicon active layer 542 arranged on the roughened current collector 546. A separator 562 includes a solid electrolyte. A cathode layer 570 includes a cathode active material layer 574, a solid electrolyte 578, and a cathode current collector 576.

Referring now to FIG. 8, scanning electron microscope images of top and side views of the anode electrode. Amorphous silicon columns are shown after formation on the roughened copper current collector.

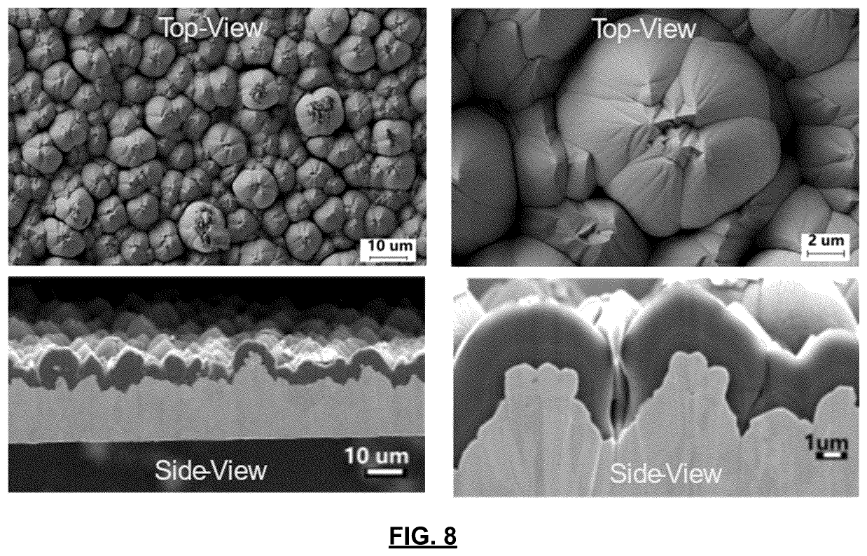

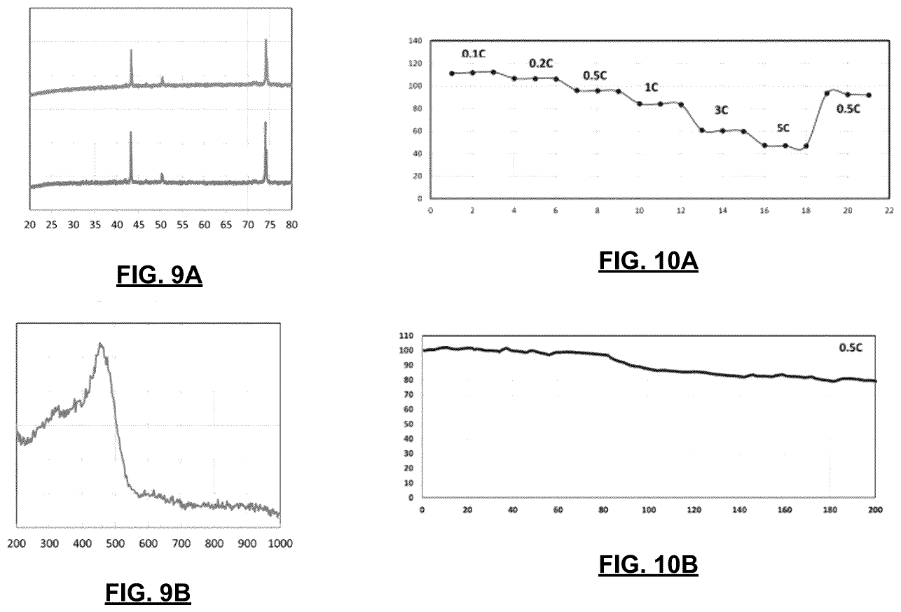

Referring now to FIGS. 9A and 9B, graphs of X-ray diffraction (XRD) profiles and Raman Spectrum of the anode electrodes are shown. In FIG. 9A, the as-deposited silicon film is amorphous with no XRD diffraction peaks corresponding to Si. In FIG. 9B, the Raman Spectrum shows a peak at 465 cm⁻¹ which can be assigned to the trans\terse optical (TO) mode of amorphous silicon (a-Si).

Referring now to FIGS. 10A and 10B, graphs show capacity and capacity retention percentage as a function of cycles for a battery cell including the anode electrode. The anode electrode has a loading of 3.5 mAh/cm². The cathode electrode has a loading of 1.41 mAh/cm². The cathode active material layer includes NCM523 as active material, lithium phosphorus sulfur chloride (LPSCl), and carbon (C) at a ratio of 5:4:04. In FIG. 10A, 25° C. rate performance is shown for the anode electrodes. In FIG. 10B, 25° C. cycling performance is shown for the anode electrodes. The amorphous silicon anode electrodes deliver good rate capability and prolonged cycle life.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A method for manufacturing an anode electrode for a battery cell comprising:
supplying a roughened anode current collector from a roll-to-roll chamber to a magnetron sputtering chamber;
routing the roughened anode current collector around a roller in the magnetron sputtering chamber;
using T sputtering targets arranged circumferentially around a portion of the roller, sputtering an amorphous silicon layer onto the roughened anode current collector to form an anode electrode, where T is an integer greater than one; and
receiving the anode electrode from the magnetron sputtering chamber at the roll-to-roll chamber.

2. The method of claim 1, wherein the roughened anode current collector is made of a material selected from a group consisting of copper, stainless steel (SS), nickel (Ni), titanium (Ti), and tin (Sb).

3. The method of claim 1, wherein the roughened anode current collector has a roughness (Rz) in a range from 0.1 μm to 12 μm.

4. The method of claim 1, wherein a thickness of the roughened anode current collector is in a range from 0.1 μm to 40 μm.

5. The method of claim 1, wherein a thickness of the amorphous silicon layer is in a range from 0.1 μm to 20 μm.

6. The method of claim 1, wherein the amorphous silicon layer comprises a plurality of silicon columns.

7. The method of claim 6, wherein a diameter of the plurality of silicon columns is in a range from 0.1 μm to 15 μm.

8. The method of claim 1, wherein an average areal capacity of the anode electrode is in a range from 4 to 30 mAh/cm².

9. The method of claim 1, wherein a DC bias voltage of the magnetron sputtering chamber is in a range from 100V to 1000V.

10. The method of claim 1, wherein a cathode power of the magnetron sputtering chamber is in a range from 0.5 KW to 30 kW.

11. A battery cell comprising:
A anode electrodes, wherein each of the A anode electrodes includes:
a roughened anode current collector; and
an anode active material layer comprising an amorphous silicon layer deposited using physical vapor deposition (PVD) onto the roughened anode current collector;
C cathode electrodes including a cathode current collector and a cathode active material layer arranged on the cathode current collector; and
S separators, where A, C and S are integers greater than one.

12. The battery cell of claim 11, wherein the roughened anode current collector is made of a material selected from a group consisting of copper, stainless steel (SS), nickel (Ni), titanium (Ti), and tin (Sb).

13. The battery cell of claim 11, wherein the roughened anode current collector has a roughness (Rz) in a range from 0.1 μm to 12 μm.

14. The battery cell of claim 11, wherein a thickness of the roughened anode current collector is in a range from 0.1 μm to 40 μm.

15. The battery cell of claim 11, wherein a thickness of the amorphous silicon layer on the roughened anode current collector is in a range from 0.1 μm to 20 μm.

16. The battery cell of claim 11, wherein the amorphous silicon layer comprises a plurality of silicon columns.

17. The battery cell of claim 16, wherein a diameter of the plurality of silicon columns is in a range from 0.1 μm to 15 μm.

18. The battery cell of claim 11, wherein an average areal capacity is in a range from 4 to 30 mAh/cm².

19. A system for manufacturing an anode electrode for a battery cell comprising:
a roll-to-roll chamber;
a magnetron chamber including a roller and T sputtering targets arranged circumferentially around a portion of the roller where T is an integer greater than one,
wherein the roll-to-roll chamber supplies a roughened anode current collector to the magnetron sputtering chamber;
wherein the roughened anode current collector is routed around the roller in the magnetron sputtering chamber and the T sputtering targets sputter an amorphous silicon layer onto the roughened anode current collector to form an anode electrode.
